(19) United States
(12) Patent Application Publication
(10) Pub. No.: US 2018/0122996 A1
(43) Pub. Date: May 3, 2018

(54) LED Flip-Chip Structure

(71) Applicant: Guangdong University of Technology, Guangzhou (CN)

(72) Inventors: Miao He, Guangzhou (CN); Sipan Yang, Guangzhou (CN); Deping Xiong, Guangzhou (CN); Junnan Zhou, Guangzhou (CN)

(73) Assignee: Guangdong University of Technology, Guangzhou (CN)

(21) Appl. No.: 15/667,673

(22) Filed: Aug. 3, 2017

(30) Foreign Application Priority Data
Oct. 27, 2016 (CN) 201610958505.8

(51) Int. Cl. H01L 33/48; H01L 33/62; H01L 33/60; H01L 33/64; H01L 33/44

(52) U.S. Cl. CPC H01L 33/486; H01L 33/62; H01L 33/60; H01L 2224/04; H01L 33/44; H01L 2924/18161; H01L 33/64

(57) ABSTRACT

An LED flip-chip structure is provided, wherein a silica gel, a fluorescent glue, a lens, an anti-reflection film and a packaging adhesive layer is sequentially arranged on the LED chip. The silica gel and fluorescent glue are sequentially filled within an insulating reflective cup, outside which a metal reflective cup and a light absorption layer is sequentially provided. The packaging adhesive layer is filled between the reflective cup and the lens. A sapphire substrate is pretreated to form an inverted T-shaped structure, on which a layer of epitaxial wafer of ceramic film is grown, and then a layer of high temperature resistant conductive film is grown on upper surfaces of grooves at both sides. A protrusion of the inverted T-shaped structure is uniformly coated with a thermally conductive adhesive with a certain thickness.

### PRIOR APPLICATIONS

This application claims priority to Chinese Patent Application No. CN 201610958505.8 filed on Oct. 27, 2016, which is incorporated herein in its entirety.

### FIELD OF THE INVENTION

The present invention relates to the field of LED semiconductor package technology, and more particularly to an LED package structure with high light transmittance and good heat dissipation.

### BACKGROUND OF THE INVENTION

The LED industry has attracted much attention in recent years, and LEDs have many advantages including energy saving, environmental protection, high efficiency, fast response, long service life, and not containing mercury. In order to obtain a desired brightness and color for high-power LEDs, a layer of highly refractive potting adhesive is coated on the LED chip surface, and a reflective layer is provided in the LED package structure. As the flip-chip technology becomes increasingly mature, package for the flip-chip structure is also varied. FIG. 6 shows a packaging method in the prior art, by which the flip chip is first bonded to a substrate, and then a fluorescent glue is molded on the substrate to form a five-sided encapsulation of the LED chip, and finally a packaging adhesive layer is coated on the fluorescent glue to complete the molding package of the component. However, such package has the disadvantages of low light transmittance, unsatisfactory heat dissipation and relatively large component size.

In addition, the reflective layer in some of the existing flip-chip structures is typically made of transparent plastic. With the product being smaller and the reflective layer being thinner, using such transparent plastic allows the light emitted from the LED chip to pass through the reflective layer easily, which will not only reduce the light saturation, but also result in vignetting effect in the package structure due to the refraction of light when going through the reflective layer, further affecting the LED luminous efficiency, and leading to decreased color rendering index, chromaticity coordinate offset and other problems.

### SUMMARY OF THE INVENTION

An object of the present invention is to overcome the drawbacks of the prior art by providing an LED flip-chip structure with high light-output efficiency and good heat dissipation.

The object of the present invention is achieved by the following technical solution:

An LED flip-chip structure, mainly including LED chip, a packaging adhesive layer (silicone or epoxy), reflective cups, a fluorescent glue, conductive films, bonding pads, a lens, an anti-reflection film and a silica gel layer used to improve the light transmittance and reduce the reflection effect. The LED flip chip is soldered to the conductive films by the respective bonding pad, and two conductive films are spaced apart and insulated from each other. The right triangular insulating reflective cup is arranged on and connected with the conductive films to reflect part of light emitted from side surfaces of the LED chip and fix the LED package pattern. A ceramic film for heat dissipation which uses sapphire as the substrate and has good thermal conductivity, fast heat dissipation, light weight, and low fluorescence intensity attenuation (the conductive films are grown on upper surfaces of grooves at both sides of the inverted T-shaped ceramic film, respectively) is further provided at a bottom of the conductive film. The sapphire-substrate ceramic film protrudes upwardly between the conductive films to form a protrusion that isolates the conductive films, increasing the contact surface with the conductive films, the chip and the bonding pads, and offering effective heat transfer and dissipation to the LED chip. Each bonding pad is electrically connected at a top with a fillet of the LED chip, and joints between surfaces of the two conductive films and the bonding pads are plated with the corresponding electrodes (electrodes are optional, i.e., d_{thickness of electrode plated at the joint between the bonding pad and the conductive film}≥0), wherein, the width of the protrusion is adjustable: a narrow protrusion just isolates the high temperature resistant conductive films in grooves at both sides to prevent direct conduction therebetween, thus playing a role of insulation; while in case of a wide protrusion, the wider the protrusion is, the greater the contact surface with the chip is, and the faster the heat dissipation is. Similarly, the height of the protrusion is adjustable. When not high enough, the protrusion needs to be filled with thermally conductive adhesive, while when the protrusion is appropriate in height, no thermally conductive adhesive layer is needed, and the ceramic film protrusion continues to increase in height, replacing the thermally conductive adhesive layer at a corresponding location.

Specifically, composition and height of the protrusion of the present invention include the following four solutions:

Solution 1: The protrusion is formed only by a sapphire substrate, a middle portion of which is raised up and extends all the way to and abuts against the bottom of the LED chip to accelerate the heat dissipation.

Solution 2: The protrusion is formed by a sapphire substrate and a ceramic film, wherein the ceramic film is grown on a surface of the sapphire substrate, a middle portion of which is raised up and extends all the way to the bottom of the LED chip, to cause an upper surface of the ceramic film to abut against the bottom of the LED chip, thus accelerating the heat dissipation of the LED chip.

Solution 3: The protrusion is formed by a sapphire substrate and a thermally conductive glue layer. A middle portion of the sapphire substrate is raised up to a certain height without touching the LED chip. A gap between the protrusion and the LED chip is filled with the thermally conductive adhesive layer such that the heat generated by the LED chip is quickly dissipated by the thermally conductive adhesive layer and the sapphire substrate.

Solution 4: The protrusion is formed by a sapphire substrate, a ceramic film and a thermally conductive adhesive layer. The ceramic film is grown on a surface of the sapphire substrate, and a middle portion of the sapphire substrate is raised up to a certain height, but the upper surface of the ceramic film does not touch the LED chip. A gap between the ceramic film and the LED chip is filled with the thermally conductive adhesive layer such that the heat generated by the LED chip is quickly dissipated by the thermally conductive adhesive layer, the ceramic film and the sapphire substrate.

The LED chip and the bonding pads are located at the bottom of the insulating reflective cup, and the bottom of the bonding pad is matched with the conductive film and then electrically connected therewith (it is also possible that the conductive film is plated with an electrode and then welded with the bonding pad). Similarly, electrodes are respectively plated on both ends of the conductive films, and a gold wire is welded at each electrode to connect to the outside and form a closed loop. The silica gel layer, the fluorescent glue, the lens, the anti-reflection film and the packaging adhesive layer are arranged within the insulating reflective cup and sequentially cover the LED chip from inside out. As a preferred embodiment of the present invention, the silica gel layer and the fluorescent glue are mainly applied to multiple faces of the LED chip (excluding a small portion of the bottom surface between the two bonding pads) to form a multi-sided encapsulation of the chip, so that the luminous surface of the package component is increased, and the overall luminous efficiency of the LED component is improved.

As a preferred embodiment of the present invention, in order to improve the light transmittance, the silica gel layer is made of a highly refractive transparent silica gel, which is located between the LED chip and the fluorescent glue, thereby effectively reducing the photon loss at an interface and improving the light output efficiency. In addition, the transparent silica gel layer can also provide mechanical protection and stress relief for the chip, and as a light-guiding structure, the silica gel layer also has advantages of high transmittance, good thermal stability, good fluidity, easy spraying, etc. Moreover, the transparent silica gel layer has low moisture absorption, low stress, anti-aging and other characteristics, which can improve the reliability of LED package. In the actual packaging of LED, the LED chip is placed in a transparent silica gel solution for coating treatment through electric heating, rotation, impregnation and other methods. After a period of time, the LED chip is taken out and then, once the uniformly covered silica gel cools and curdles, put into the vacuum oven for further drying and solidification treatment for 1 h, so that multiple surfaces of the LED chip are coated with a silica gel layer. The above coating process needs to be repeated 4-5 times in order to obtain a more uniform silica gel layer. Besides, a multi-surface silica gel encapsulation can be formed around the LED chip through changing the mixed gel proportion, drying process and other processes, so as to achieve multi-sided illumination.

As a preferred embodiment of the present invention, in order to obtain a better light transmittance, the phosphor, which has been subjected to re-grinding and purification, are internally mixed or externally coated on a surface of the curved lens (with a convex top and a concave bottom), and are separated from the chip through an optical structure design, so that the distance between the phosphor and the chip is further enlarged (specifically, the remote phosphor technology is applied to arrange at an interval the fluorescent glue and the lens internally mixed or externally coated with phosphor, so that the phosphors on the lens and the fluorescent glue are both separated from the chip), the operating temperature of the phosphor is reduced, and the uniformity and stability of the phosphor are improved, thus allowing more light which emits more uniform, increasing the luminous flux, improving the lighting quality and light output efficiency of the white LED, and improving the packaging efficiency. Moreover, the phosphor being mixed within the lens can block water and oxygen, avoiding pollution due to direct contact of the phosphor with the outside which further affects the luminous efficiency.

Further, in order to avoid the vignetting effect and improve the lighting quality, a metal reflective cup is provided outside the insulating reflective cup for enhancing the reflection effect. Most of the light emitted from side surfaces of the LED chip is reflected by the insulating reflective cup, part of the light continues to pass through the insulating reflective cup and is reflected back by the metal reflective cup, so that the light is more concentrated and will not scatter sideward. Further, the light saturation, chromaticity coordinates, color temperature, luminous efficiency, color contrast (color gamut), luminous efficiency (luminous quality), light emitting uniformity and color rendering (color rendering index) of the light emitted from the LED chip can be maintained, and the thermal stability problem of the chip during the illumination can be solved to obtain an ideal luminous effect.

Further, although the metal reflective cup can reflect the vast majority of the light passing through the insulating reflective cup, a small portion of the light can emit from the metal reflective cup interface. Thus, in order to further avoid the vignetting effect and get better luminous quality, a light absorption layer is provided outside the metal reflective cup for avoiding light scattering, and all the light emitted from the interface of the metal reflective cup is absorbed by the light absorption layer, so as to substantially avoid the light scattering and the vignetting effect, and ultimately ensure that the emitting light is emitted in parallel only in the vertical direction (quality light source in the vertical plane).

Further, in order to improve the heat dissipation effect of the LED chip, the bottom of the LED chip between the bonding pads is filled with the thermally conductive adhesive for heat dissipation. Specifically, thermally conductive adhesive is completely filled between the protrusion of the sapphire-substrate ceramic film and the two bonding pads at the bottom of the LED chip to form a thermally conductive adhesive layer. A portion of the heat generated by the LED chip is dissipated quickly through the bonding pads, the conductive films and the ceramic film, and the bonding pad, the conductive film, the thermally conductive adhesive layer and the ceramic film contact with each for heat transfer, improving the heat dissipation efficiency and effect; the other portion of heat can be quickly dissipated through the thermally conductive adhesive layer, the ceramic film and other heat dissipation structures, enhancing the heat dissipation effect. In addition, in order to ensure the heat dissipation effect, it is required to strictly control that the sum of the height of the protrusion in the ceramic film inverted T-shaped structure and the thickness of the thermally conductive adhesive layer is equal to the sum of the height of the bonding pad and the thickness of the conductive film, that is, the top of the thermally conductive adhesive layer completely abuts against the bottom of the LED chip, and the bottom of the thermally conductive adhesive layer completely abuts against the protrusion of the ceramic film (i.e. the thermally conductive adhesive is completely filled between the bottom of the flip chip and the upper surface of the ceramic film protrusion, which can be expressed with a simple relation as: d_{thickness of the sapphire-substance ceramic film protrusion}=d_{bonding pad thickness}+d_{thickness of electrode plated at the joint between the bonding pad and the conductive film}+d_{thickness of high temperature resistant conductive film}, wherein d_{thickness of electrode plated at the joint between the bonding pad and the conductive film}≥0).

As a preferred embodiment of the present invention, the conductive film is made of a film having high temperature resistance, good electrical conductivity and fast heat dissipation (good thermal conductivity), which can be obtained by magnetron sputtering, chemical vapor deposition, hydride vapor phase epitaxy, photolithography and other methods. The specific method is as follows: the sapphire substrate is pretreated in a magnetron sputtering experiment to form an inverted T-shaped structure; and then a layer of epitaxial wafer of ceramic film is grown on the surface of the sapphire substrate of the inverted T-shaped structure; similarly, a layer of conductive film is grown on upper surfaces of grooves at both sides of the sapphire-substrate ceramic film, respectively. Specifically, the selected sputtering target material is ZnO doped with an appropriate amount of Mg and Ga (ZnO:Mg:Ga). In the experimental environment, the base pressure is in the order of 10⁻⁵, sputtering pressure is 4 Pa-5 Pa, and sputtering power is maintained at 200 W; after 2 h growth, 600° C. annealing is adopted in N₂ environment. The conductivity, thickness and other properties of the film are tested and analyzed by means of X-ray diffraction, UV/VIS spectrophotometer and scanning electron microscope. The high temperature resistant conductive film prepared by this method has a crystal structure similar to that of ZnO, and has advantages of high light transmittance, superior conductivity, etc.

Similarly, as a preferred embodiment of the present invention, in order to achieve a better heat dissipation effect, prevent the chip from overheating and prolong the LED service life, the heat-dissipating ceramic film is an AlN or SiC film using sapphire as the substrate. Specifically, the processing steps of the sapphire-substrate ceramic film are as follows: photolithography, hollowed-out process and other pretreatments are performed in accordance with the thickness and height ratios of the components in the structural diagram to form an inverted T-shaped structure, and then a layer of ceramic film is grown on an upper surface of the inverted T-shaped sapphire-substrate structure, another layer of high temperature resistant conductive film is grown on upper surfaces of grooves at both sides of the inverted T-shaped ceramic film according to the proportions of the various components in the structural diagram, and electrodes are respectively plated on the high temperature resistant conductive film at positions matched with the bonding pads (optional, i.e. d_{thickness of electrode plated at the joint between the bonding pad and the conductive film}≥0). A circuit can be prepared on the ceramic film with the sapphire substrate by magnetron sputtering, solvent evaporation, electrospray and photolithography, and sputtering coating, electro-/electrochemical deposition or photolithography hollowed-out can be used to change the circuit thickness, so as to offer products with high line accuracy, high flatness, good thermal conductivity, good heat dissipation and other advantages. In actual packaging, sorting equipment is used to arrange flip chips according to a fixed periodic sequence. The conductor chip pads are matched with electrode areas of the chips. The respective conductor chip pads are directly and closely abutted against the electrodes plated on the high temperature resistant conductive films to allow the bonding pads to be electrically connected to the conductive films. At the same time, the ceramic film with the sapphire substrate is cut in the circumferential arc direction shown in the package structure to remove the excess ceramic film so as to form a separate component structure. Finally, a plurality of individual components are arranged in combination to form complete packaged components, as shown in FIG. 5.

As a preferred embodiment of the present invention, the fluorescent glue is made of phosphor and silica gel. In order to obtain a better light-transmitting effect, rare earth phosphor (having a larger particle size) is used, which is characterized by high brightness, stable physicochemical properties, good high temperature resistance performance, and capability of withstanding high-power electron beams, high-energy radiation and strong ultraviolet light. The phosphor is subjected to repeated grinding and purification to a particle size of about 5 um so as to get a higher light output efficiency and better luminous efficiency, and the weight ratio of the mixed phosphor and silica gel (ordinary silica gel) is 10:90.

As a preferred embodiment of the present invention, in order to improve the reflection effect of the insulating reflective cup and the fixation effect at the time of packaging, the package structure is symmetrical with respect to a central axis, so half cross-sections of the insulating reflective cup (a half cross-section is a cross-section intercepted by a plane formed by the center axis and any radius from the insulating reflective cup) are designed as right triangles. The angle relation is shown in FIG. 8, wherein the larger angle in the right triangle meets α∈(45°,90°) to always guarantee β≥90°, so that the light incident on the surface of the insulating reflective cup can be reflected back better to improve the light transmittance. Similarly, such angle design is also considered for another right triangle.

Further, the insulating reflective cup is made of a transparent insulating material with nonuniform density distribution, and the density p and the thickness d of the insulating reflective cup are inversely proportional to the distance r between the insulating reflective cup and the chip, that is, the density and thickness of the insulating reflective cup gradually decrease from inside out (which can be expressed with a simple relation as: ρ=k₁/r; similarly, d=k₂/r, wherein k₁ and k₂ are different proportion coefficients). The area with more light emitted is accompanied with higher density and greater thickness of the insulating reflective cup, so as to enhance the reflection of the incident light at the incident surface of the insulating reflective cup (i.e. the hypotenuse of the right triangle in the structural diagram), that is, to reduce the light emitted at the emergent surface of the insulating reflective cup (i.e. the erect right-angled side of the right triangle). The amount of light reflected by the metal reflective cup is reduced accordingly, and interference of the light in the subsequent packaging component is avoided from the very beginning.

As a preferred embodiment of the present invention, a too thick silica gel coating will affect the light-emitting efficiency of the LED chip, increases the light loss, and causes serious problems of self-heating and difficult heat dissipation of the LED chip; while a too thin silica gel coating will also affect the light-emitting efficiency of the LED chip. Therefore, the thickness of the silica gel layer is designed to be 0.05 mm in the present invention.

As a preferred embodiment of the present invention, the high temperature resistant conductive film and the sapphire-substrate ceramic film collectively replace the conventional heat-dissipating aluminum base; without the limitation of the aluminum base, the size of the packaged component is significantly reduced to be very close to the chip area, and the packaged component has the advantages of precise manufacturing, high integration, light weight, etc., truly achieving a chip scale integrated LED package.

The operating processes and principles of the invention are that: the majority of the light emitted by the plurality of faces of the LED chip is concentrated in the vertical direction and emitted parallelly after passing through the silica gel layer, the fluorescent glue, the lens, the anti-reflection film and the packaging adhesive layer, and the light emitted sideward can be reflected by the insulating reflective cup. A small portion of the light refracted by the insulating reflective cup reaches the metal reflective cup and is reflected by the metal reflective cup. A very small amount of light can even penetrate through the metal reflective cup, but a light absorption layer is provided behind the metal reflective cup, which can completely absorb the light penetrating through the metal reflective cup, thus avoiding scattering of light to outside and occurrence of vignetting effect. The bonding pad at the bottom of the LED chip is electrically connected to the conductive film through the electrode. The conductive film is provided at the bottom with a ceramic film for heat dissipation, and a thermally conductive adhesive layer is filled between the bottom of the LED chip and the ceramic film, so the heat generated by the LED chip can be quickly dissipated through the bonding pad, the conductive film and the ceramic film, or through the thermally conductive adhesive layer and the ceramic film. The bonding pad, the conductive film, the thermally conductive packaging adhesive layer and the ceramic film contact with each to accelerate heat dissipation, improving the heat dissipation effect. The invention has the advantages of high light transmittance, good heat dissipation effect and small package size.

Compared with the prior art, the invention also has the following advantages:

(1) The LED flip-chip structure of the invention uses the conductive film and the ceramic film instead of the traditional heat dissipation aluminum substrate, so that the package size is very close to the LED chip area, leading to a light package weight and an increased precision and integration level of packaging and manufacturing, thus achieving a chip-level integration packaging in real sense.

(2) in the present invention, surfaces of the LED chip are coated with a highly refractive transparent silica gel, which can effectively reduce loss of photon at the interface and improve the light emitting efficiency of the LED device. At the same time, the silica gel layer can provide physical protection for the LED chip and release the stress generated during packaging, and has a high transmittance, a high refractive index, good thermal stability, good fluidity, easy spraying and other advantages, and low hygroscopicity, low stress, anti-aging and other characteristics.

(3) In the present invention, the silica gel layer, the fluorescent glue, the lens, the anti-reflection film and the packaging adhesive layer are sequentially covered on the LED chip, wherein the silica gel layer can increase the light transmittance. Transmittance of the lens can also be increased by being internally mixed or externally coated with phosphor (the thickness of the externally coated phosphor is 0.02 mm) using screen printing technique. The anti-reflection film can effectively reduce the reflection of light and increase the light transmittance.

(4) The LED flip-chip structure of the invention adopts an insulating reflective cup with a right triangle structural design, and has a metal reflective cup with a right angle trapezoidal structure and a light absorption layer arranged behind the insulating reflective cup. The reflective cup can concentrate and reflect back the light to the maximum extent, and the light absorption layer will completely absorb the light penetrating through the reflective cup to avoid sideward scattering of light, thus effectively avoiding occurrence of vignetting effect.

(5) The LED flip-chip structure of the invention adopts the sapphire-substrate ceramic film as the heat dissipation material, thus the heat resistance of the LED chip is remarkably improved. With the thermally conductive adhesive layer at the bottom of the LED flip chip, a part of heat generated by the LED chip can be dissipated quickly through the ceramic film and the thermally conductive adhesive layer, similarly, the high temperature resistant conductive films are directly abutted against the two bonding pads of the chip by means of the plated electrodes, so a part of heat generated by the LED chip can be dissipated quickly through the bonding pads and the high temperature resistant conductive films, improving the heat dissipation efficiency and effect.

(6) In the present invention, the chips are placed in a transparent silica gel solution for electric heating, and after a period of time, the chips are taken out with a uniform silica gel coating. The above operation is repeated 4-5 times, and then the chips are baked in an oven for drying and solidification for one hour. This method makes the silica gel layer more uniform, the heated silica gel will not contain bubbles, and the thickness of the silica gel layer is also under good control, so the method is much better compared to the traditional silica gel coating.

### BRIEF DESCRIPTION OF THE DRAWINGS

FIG. 1 is a schematic diagram of solution 1 of the LED flip-chip structure provided by the present invention.

FIG. 2 is a schematic diagram of solution 2 of the LED flip-chip structure provided by the present invention.

FIG. 3 is a schematic diagram of solution 3 of the LED flip-chip structure provided by the present invention.

FIG. 4 is a schematic diagram of solution 4 of the LED flip-chip structure provided by the present invention.

FIG. 5 is a schematic diagram of an overall structure obtained by arrangement and combination of a plurality of individual LED flip-chip structures provided by the present invention.

FIG. 6 is a schematic diagram of an LED flip-chip structure in the prior art with five-side light emission.

FIG. 7 is a schematic diagram of an LED flip chip in the prior art using a molding package structure.

FIG. 8 is a schematic diagram of an angle relation between two insulating reflective cups of the LED flip-chip structure provided by the present invention.

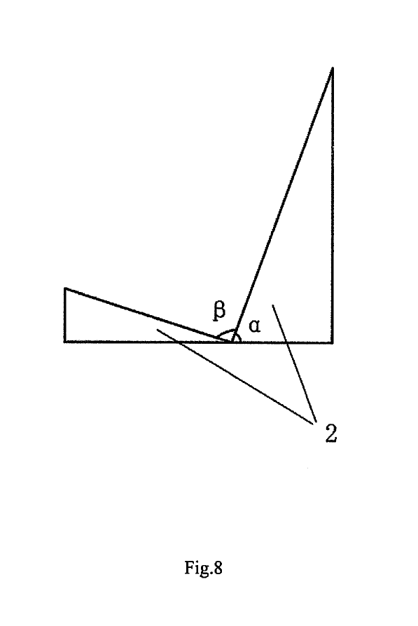

Description of the labels in the above drawings are as follows:

1—packaging glue layer, 2—insulating reflective cup, 3—light absorption layer, 4—fluorescent glue, 5—conductive film, 5a—substrate, 6—LED chip, 7—bonding pad, 8—ceramic film, 9—lens, 10—anti-reflection film, 11—metal reflective cup, 12—silica gel layer, 13—thermally conductive glue layer, 14—sapphire substrate, 15—heat dissipation hole.

### DETAILED DESCRIPTION OF THE EMBODIMENTS

To better clarify the purposes, technical solutions and advantages of the present invention, the present invention will be further explained in conjunction with the accompanying drawings and the embodiments.

### Embodiment 1

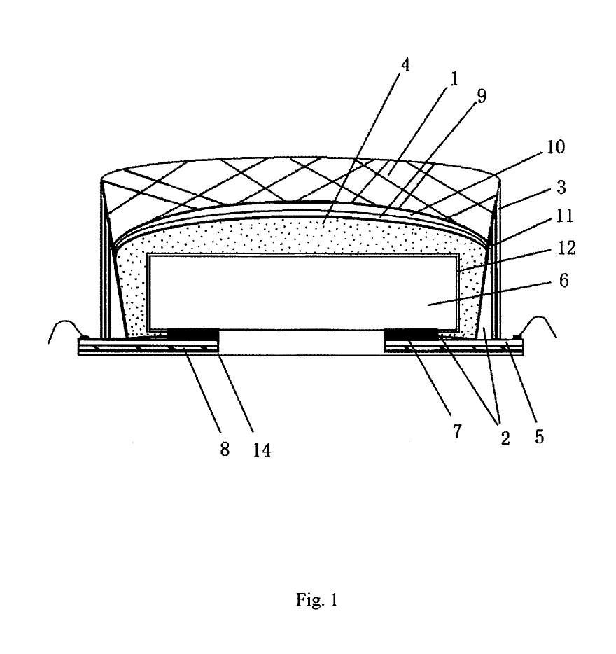

As shown in FIG. 1, the present invention discloses an LED flip-chip structure comprising an LED chip 6, an insulating reflective cup 2, a fluorescent glue 4, a packaging glue layer 1, conductive films 5, bonding pads 7, a lens 9, an anti-reflection film 10 for improving light transmittance and reducing light reflection, a silica gel layer 12, and a sapphire substrate 14. Insulation is respectively formed between the conductive films 5, and between the bonding pads 7. The insulating reflective cup 2 is arranged on and fixedly connected with the conductive films 5, for reflecting light emitted from the LED chip 6 and fixing the LED encapsulation. Below the conductive films 5 a ceramic film 8 is further provided for heat dissipation. The sapphire-substrate ceramic film 8 protrudes upwardly between the two conductive films 5 to form a protrusion that isolates the conductive films 5, increasing contact surface between the conductive film 5 and the bonding pad 7, and offering effective heat dissipation to the LED chip 6. The LED chip 6 and the bonding pads 7 are located at a bottom of the insulating reflective cup 2. Each of the bonding pads 7 is electrically connected at a bottom of the pad to the corresponding conductive film 5 through an electrode plated therebetween, and is electrically connected at a top of the pad to the LED chip, then a loop with outside circuitry is formed through gold wires. The silica gel layer 12, the fluorescent glue 4, the lens 9, the anti-reflection film 10 and the packaging adhesive layer 1 are all arranged within the insulating reflective cup 2 and sequentially cover the LED chip 6 from inside out. As a preferred embodiment of the present invention, the silica gel layer 12 and the fluorescent glue 4 are applied to a plurality of faces of the LED chip 6 (excluding a small portion of bottom surface) to form a multi-sided encapsulation of the chip, so that the packaged component emits light from several surfaces, apparently improving the luminous efficiency of the LED component.

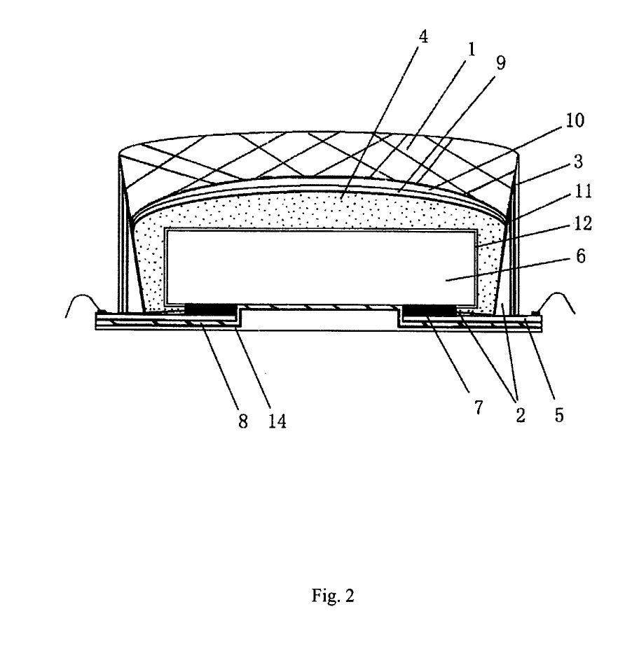

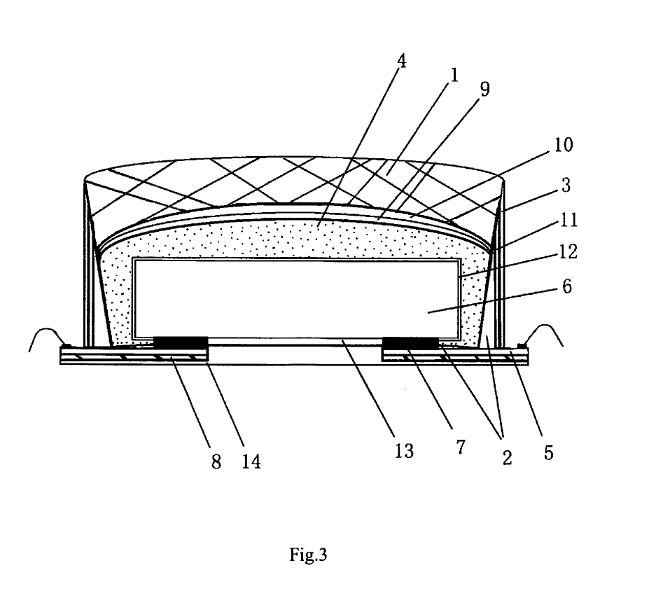

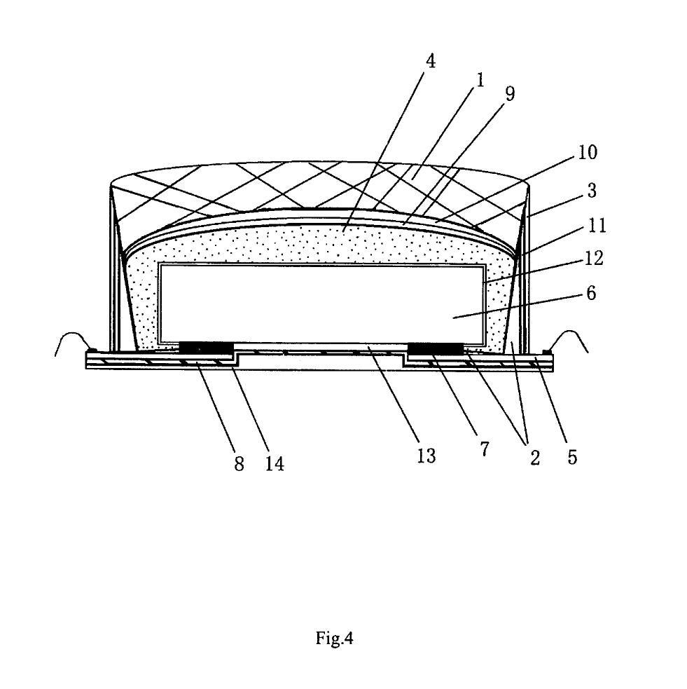

Specifically, in conjunction with FIGS. 1, 2, 3, and 4, composition and height of the protrusion in the present invention include the following four solutions:

Solution 1: The protrusion is formed only by the sapphire substrate 14, a middle portion of which is raised up and extends all the way to and abuts against the bottom of the LED chip 6 to accelerate heat dissipation.

Solution 2: The protrusion is formed by the sapphire substrate 14 and the ceramic film 8, wherein the ceramic film 8 is grown on a surface of the sapphire substrate 14, a middle portion of which is raised up and extends all the way to the bottom of the LED chip 6, to cause an upper surface of the ceramic film 8 abuts against the bottom of the LED chip 6 to accelerate heat dissipation thereof.

Solution 3: The protrusion is formed by the sapphire substrate 14 and a thermally conductive adhesive layer 13. A middle portion of the sapphire substrate 14 is raised up to a certain height without touching the LED chip 6. A gap between the protrusion and the LED chip 6 is filled with the thermally conductive adhesive layer 13 such that heat generated by the LED chip 6 is quickly dissipated by the thermally conductive glue layer 13 and the sapphire substrate 14.

Solution 4: The protrusion is formed by the sapphire substrate 14, the ceramic film 8 and a thermally conductive adhesive layer 13. The ceramic film 8 is grown on a surface of the sapphire substrate 14, and a middle portion of the sapphire substrate 14 is raised up to a height, but the upper surface of the ceramic film 8 does not contact with the LED chip 6. A gap between the ceramic film 8 and the LED chip 6 is filled with the thermally conductive adhesive layer 13 such that heat generated by the LED chip 6 is quickly dissipated by the thermally conductive adhesive layer 13, the ceramic film 8 and the sapphire substrate 14.

As a preferred embodiment of the present invention, in order to improve the light transmittance, the silica gel layer 12 is made of a highly refractive transparent silica gel, which is located between the LED chip 6 and the fluorescent glue 4, thereby effectively reducing the photon loss at an interface thereof and improving the light output efficiency. The transparent silica gel layer 12 can also provide mechanical protection and stress relief for the chip, and as a light-guiding structure, the silica gel layer 12 also has the advantages of high light transmittance, high refractive index, good thermal stability, good fluidity, easy spraying, etc. Moreover, the transparent silica gel layer 12 has low moisture absorption, low stress, anti-aging and other characteristics, which can significantly improve the reliability of LED package. In practice, the LED chip 6 is placed in a transparent silica gel solution for coating treatment through electric heating; after a period of time, the LED chip 6 is taken out and then, once the uniformly covered silica gel cools and curdles, put into a vacuum oven for further drying and solidification treatment for 1 h, so that multiple surfaces of the LED chip 6 are coated with a silica gel layer 12. The above coating process needs to be repeated 4-5 times in order to obtain a more uniform silica gel layer. Besides, a multi-surfaces silica gel package can be formed around the LED chip 6 through changing the mixed gel proportion, drying process and other processes, so as to emit light from several surfaces.

As a preferred embodiment of the present invention, in order to obtain a better light transmittance, phosphor can be internally mixed or externally coated on a surface of the lens 9 through electrophoretic deposition, sputter deposition coating, spin coating, etc., which will not only improve the uniformity of the phosphor, but also improve the package efficiency.

Further, in order to avoid the vignetting effect and improve the light quality, a metal reflective cup 11 for enhancing the reflection effect is provided outside the insulating reflective cup 2. A part of light emitted from the LED chip 6 is reflected by the insulating reflective cup 2, the other part penetrates through the insulating reflective cup 2 and is reflected again by the metal reflective cup 11, so that the light is more concentrated and will not scatter sideward. Further, the light saturation, the chromaticity coordinate, the color contrast, and the color rendering index of the light emitted from the LED chip 6 can be maintained, and a desired luminous effect can be obtained.

Further, although the metal reflective cup 11 can reflect the vast majority of the light, a small portion of the light can penetrate through the metal reflective cup 11. Thus in order to obtain better luminous quality, a light absorption layer 3 for avoiding light scattering is provided outside the metal reflective cup 11, and all the light penetrating through the metal reflective cup 11 is absorbed by the light absorption layer 3, so as to avoid the vignetting effect.

Further, in order to improve the heat dissipation effect of the LED chip 6, the bottom of the LED chip 6 between the bonding pads 7 is filled with a thermally conductive adhesive layer 13 for heat dissipation. Specifically, the thermally conductive adhesive is completely filled between the protrusion formed by the sapphire-substrate ceramic film 8 and the bottom of the LED chip 6 to form a thermally conductive adhesive layer 13. A portion of heat generated by the LED chip 6 is dissipated quickly through the bonding pad 7, the conductive film 5 and the ceramic film 8, and the other portion of heat can be quickly dissipated through the thermally conductive adhesive layer 13 and the ceramic film 8, enhancing the heat dissipation effect; the bonding pad 7, the conductive film 5, the thermally conductive adhesive layer 13 and the ceramic film 8 contact with each other for heat transfer, improving the heat dissipation efficiency. In addition, in order to ensure the heat dissipation effect, it is required to strictly control that sum of the height of the protrusion in the ceramic film 8 inverted T-shaped structure and the thickness of the thermally conductive adhesive layer 13 is equal to sum of the height of the bonding pad 7 and the thickness of the conductive film 5, that is, the thermally conductive adhesive layer 13 is completely in contact with, at a top thereof, the bottom of the LED chip 6, and completely abuts against, at a bottom thereof, the protrusion of the ceramic film 8.

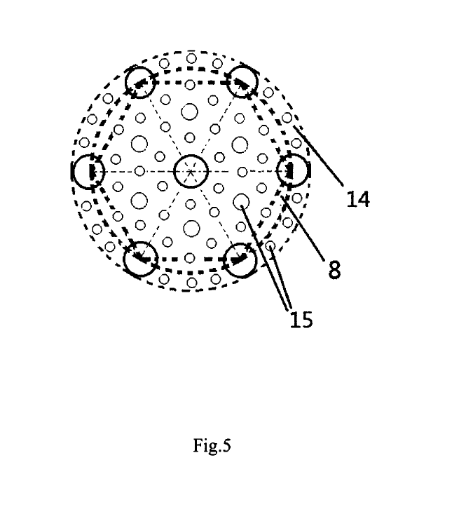

As a preferred embodiment of the present invention, the conductive film 5 is made of a high temperature resistant film, which can be obtained by magnetron sputtering, chemical vapor deposition, hydride vapor phase epitaxy, photolithography and other methods. The specific method is as follows: a layer of epitaxial wafer of ceramic film 8 is grown on upper surfaces of grooves at both sides of the inverted T-shaped sapphire substrate. Similarly, a layer of high temperature resistant conductive film 5 is further grown on an upper surface of the sapphire-substrate ceramic film 8. Specifically, the selected sputtering target material is ZnO doped with an appropriate amount of Mg and Ga (ZnO:Mg:Ga). The results are analyzed by means of X-ray diffraction, UV/VIS spectrophotometer and scanning electron microscope. The high temperature resistant conductive film 5 prepared by this method has a high light transmittance, a low resistivity, a superior conductivity and other advantages. As shown in FIG. 5, an individual packaged component is cut in a circumferential arc direction (small circles in the figure) to remove an excess portion of the sapphire-substrate ceramic film 8 to form a complete component structure. Considering the overall effect, when arranging and assembling a plurality of individual LED components, each bottom thereof is provided on the ceramic film 8 and the sapphire substrate 14 for heat dissipation, and a number of heat dissipation holes with varied sizes are provided in the sapphire substrate 14 to get better heat dissipation effect.

As a preferred embodiment of the present invention, in order to achieve a better heat dissipation effect, prevent the chip from overheating and prolong the LED service life, the ceramic film 8 with a sapphire substrate is adopted. Specifically, the processing steps of the sapphire-substrate ceramic film 8 are as follows: pretreatments such as photolithography, hollowed-out process are performed on the sapphire substrate 14 in accordance with thickness and height ratios between the components in the structural diagram to form an inverted T-shaped structure, and then a layer of ceramic film 8 is grown on upper surfaces of grooves of the inverted T-shaped sapphire-substrate structure, after that another layer of high temperature resistant conductive film 5 is grown on the upper surface of each groove of the inverted T-shaped ceramic film 8 according to the proportions of the various components in the structural diagram. A circuit can be prepared on the ceramic film 8 by magnetron sputtering and photolithography, and sputtering coating, electro-/electrochemical deposition or photolithography hollowed-out can be used to change the circuit thickness, so as to offer products with high line accuracy, high flatness and other advantages. In actual packaging, sorting equipment is used to arrange flip chips according to a fixed periodic sequence. The conductor chip pads 7 are matched with electrode areas of the chips. Each of conductor chip pads 7 is directly and closely abutted against the high temperature resistant conductive film 5 through a plated electrode to allow the bonding pad 7 to be electrically connected to the conductive film 5.

As a preferred embodiment of the present invention, the fluorescent glue 4 is formed by mixing phosphor and silica gel. In order to obtain a better light-transmitting effect, on one hand, the phosphor needs to be subjected to multiple grinding and purification, and weight ratio of the mixed phosphor and silica gel is 10:90, on the other hand, different package processes are used to arrange two layers of phosphor at an interval.

As a preferred embodiment of the present invention, in order to improve the reflection effect of the insulating reflective cup 2 and the fixation effect at the time of packaging, the individual LED package structure is symmetrical with respect to an central axis, so half cross-sections of the insulating reflective cup 2 (a half cross-section is a cross-section intercepted by a plane formed by the center axis and any radius from the insulating reflective cup 2) are designed as right triangles, and the larger angle in the right triangle meets α∈(45°,90°) to always guarantee β≥90°.

Further, the insulating reflective cup 2 is made of a transparent insulating material with nonuniform density distribution, and the density p and the thickness d of the insulating reflective cup 2 are inversely proportional to a distance r between the insulating reflective cup 2 and the LED chip 6, that is, the density and thickness of the insulating reflective cup 2 gradually decrease from inside out.

As a preferred embodiment of the present invention, a too thick silica gel layer 12 will affect the light-emitting efficiency of the LED chip 6, increase the light loss, and cause serious problems of self-heating and difficult heat dissipation of the LED chip 6. While a too thin silica gel layer 12 will also affect the light-emitting efficiency of the LED chip 6. Therefore, the thickness of the silica gel layer 12 is designed to be 0.05 mm in the present invention.

As a preferred embodiment of the present invention, the high temperature resistant conductive film 5 and the sapphire-substrate ceramic film 8 collectively replace the conventional heat-dissipating aluminum substrate. Without limitation of the aluminum substrate, size of the packaged component is significantly reduced to be very close to the chip area, and the packaged component has the advantages of precise manufacturing, high integration, light weight, etc., truly achieving a chip scale integrated LED package.

As a preferred embodiment of the present invention, the thermally conductive adhesive layer 13 may be further replaced by the ceramic film 8, i.e., the protrusion height of the ceramic film continues to increase and the increased height is equal to the thickness of the thermally conductive adhesive layer.

The operating process and principle of the invention are as follows: the majority of light emitted from the LED chip 6 is concentrated in the vertical direction and emitted parallelly after passing through the silica gel layer 12, the fluorescent glue 4, the lens 9, the anti-reflection film 10 and the packaging adhesive layer 1, and the light emitted sideward can be reflected by the insulating reflective cup 2. A small portion of the light refracted by the insulating reflective cup 2 reaches the metal reflective cup 11, and is reflected by the metal reflective cup 11. A very small amount of light can even penetrate through the metal reflective cup 11, but a light absorption layer 3 is provided behind the metal reflective cup 11, which can completely absorb the light penetrating through the metal reflective cup 11, thus avoiding the vignetting effect. Each bonding pads 7 at the bottom of the LED chip 6 is electrically connected to a conductive film 5 through a plated electrode. A ceramic film 8 is provided at a bottom of each conductive film 5 for heat dissipation, and a thermally conductive adhesive layer 13 is filled between the bottom of the LED chip 6 and the ceramic film 8, so heat generated by the LED chip 6 can be quickly dissipated through the bonding pad 7, the conductive film 5 and the ceramic film 8, or through the thermally conductive adhesive layer 13 and the ceramic film 8. The bonding pad 7, the conductive film 5, the thermally conductive packaging adhesive layer 1 and the ceramic film 8 contact with each other, improving the heat dissipation efficiency. The invention has advantages of high light transmittance, good heat dissipation effect and small package size.

### Embodiment 2

As shown in FIG. 1, an LED flip-chip structure, including an LED chip 6, a lens 9 internally mixed or externally coated with phosphor, a fluorescent glue 4, an insulating reflective cup 2, a metal reflective cup 11, an anti-reflection film 10, a packaging adhesive layer 1, a transparent silica gel layer 12, bonding pads 7, high temperature resistant conductive films 5, a light absorption layer 3, a ceramic film 8 with a sapphire substrate, and a thermally conductive adhesive layer 13. The LED chip 6 with a flip-chip structure is packaged within the fluorescent glue 4. Surfaces of the LED chip is coated with a transparent silica gel layer 12 having a high refractive index. Two conductor bonding pads 7 at a front side of the LED chip 6 are abutted against and electrically connected to the high temperature resistant conductive films 5 through plated electrodes respectively. The lens 9 internally mixed or externally coated with phosphor is provided on an upper surface of the fluorescent glue 4. The anti-reflection film 10 for enhancing the light transmittance is provided on an upper surface of the lens 9. An uniform layer of the packaging adhesive layer 1 is sprayed on an upper surface of the anti-reflection film 10. The fluorescent glue 4, the lens 9, the anti-reflection film 10, and the packaging glue layer 1 are filled within the insulating reflective cup 2, the metal reflective cup 11 is provided outside the insulating reflective cup 2, and the light absorption layer 3 is provided outside the metal reflective cup 11.

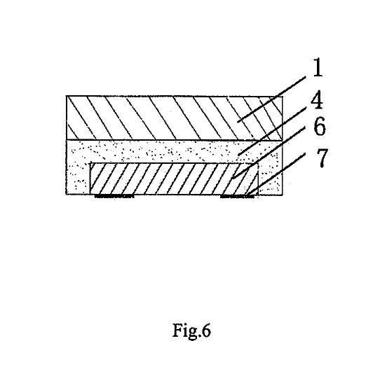

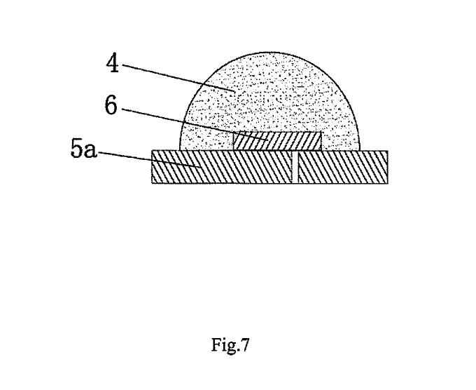

FIG. 6 shows an LED flip-chip structure in the prior art with five-sided light emission, including an LED chip 6. Chip bonding pads 7 are provided at a front side of the LED chip 6, and five faces of the LED chip 6 are coated with a uniformly mixed fluorescent glue 4. A packaging adhesive layer 1 is provided outside of the fluorescent glue 4. FIG. 7 shows a flip chip in the prior art using molding package. Specifically, LED chips 6 abut directly against substrate 5a through conductor bonding pads, respectively, and are covered by a fluorescent glue 4. In the above LED package structure, the distance between the phosphor and the chip is close, so heat released by the chip will be easily absorbed by the phosphor (stronger thermal radiation). However, the small size of the LED prohibits effective heat exchange with the outside world, and the packaged components will be damaged due to bad heat dissipation, thus the stability and service life will be affected.

The high temperature resistant conductive film 5 can be obtained by magnetron sputtering, chemical vapor deposition, hydride vapor phase epitaxy, photolithography and other methods. In the magnetron sputtering experiment, a layer of epitaxial wafer of ceramic film 8 is grown on the upper surface of the inverted T-shaped sapphire substrate. Similarly, a layer of high temperature resistant conductive film 5 is further grown on the upper surface of grooves at both sides of the sapphire-substrate ceramic film 8. Specifically, the selected sputtering target material is ZnO doped with an appropriate amount of Mg and Ga (ZnO:Mg:Ga). Experiment results are analyzed by means of X-ray diffraction, UV/VIS spectrophotometer and scanning electron microscope. The high temperature resistant conductive film 5 prepared by this method has a high light transmittance, a low resistivity, a superior conductivity and other advantages. As shown in FIG. 5, the sapphire-substrate ceramic film 8 is cut in the circumferential arc direction to remove the excess portion of the sapphire-substrate ceramic film to form a separate component structure.

In order to obtain a better light transmittance, the lens 9 is internally mixed or externally coated with phosphor, which improves the uniformity of the phosphor and the emitted light, and improves the packaging efficiency. The mixed phosphor in the packaged adhesive layer is subjected to multiple grinding and purification, with the weight ratio of the phosphor and silica gel in the fluorescent glue controlled to be 10:90. An anti-reflection film for enhancing the light transmittance is further provided on the upper surface of the lens 9. A highly refractive transparent silica gel layer 12 is uniformly coated on surfaces of the LED chip 6, which is located between the LED chip 6 and the fluorescent glue 4, thereby effectively reducing the photon loss at an interface and improving the light transmittance efficiency. In addition, the transparent silica gel layer 12 can also provide mechanical protection and stress relief for the chip, and as a light-guiding structure, the silica gel layer also has the advantages of high transmittance, high refractive index, good thermal stability, good fluidity, easy spraying, etc. Moreover, the transparent silica gel layer 12 has low moisture absorption, low stress, anti-aging and other characteristics, which can improve the reliability of LED package.

In order to achieve a better heat dissipation effect, prevent the chip from overheating and prolong the LED service life, a circuit can be prepared on the sapphire-substrate ceramic film 8 by magnetron sputtering and photolithography, and sputtering coating, electro-/electrochemical deposition or photolithography hollowed-out can be used to change the circuit thickness, so as to offer products with high line accuracy, high flatness and other advantages. Sorting equipment is used to arrange flip chips 6 according to a fixed periodic sequence. The conductor chip pads 7 are matched with electrode areas of the chips. The conductor chip pads 7 are directly and closely abutted against the high temperature resistant conductive films 5 of the grooves at both sides of the inverted T-shaped structure, respectively, and the thermally conductive adhesive layer 13 is completely filled between and abutted against the two bonding pads at the front side of the flip chip, strictly ensuring that the protrusion height of the inverted T-shaped structure is equal to the sum of the thicknesses of the chip pad, the plated electrode and the high temperature resistant carrier film.

In order to avoid the vignetting effect and increase the light quality, a metal reflective cup 11 is provided outside the insulating reflective cup 2, and a light absorption layer 3 is provided outside the metal reflection cup 11. The insulating reflective cup 2 is made of an insulating transparent material with nonuniform density distribution, and the density and thickness of the insulating reflective cup are designed to be inversely proportional to a distance between the insulating reflective cup and the chip; the larger angle in the right triangle meets α∈(45°,90°) to always guarantee β≥90°.

The LED chip 6 is placed in a transparent silica gel solution for coating treatment through electric heating, and taken out after a period of time. The above operation is repeated 3-4 times, until the silica gel uniformly coated on the chip is cooled and curdled. Then the LED chip 6 is put into the vacuum oven for further drying and solidification treatment for 1 h, so that multiple surfaces of the LED chip 6 are coated with a silica gel layer 12. The coating process needs to be repeated 4-5 times in order to obtain a more uniform silica gel layer with a thickness of 0.05 mm. Besides, a multi-surfaces silica gel encapsulation around the LED chip may also be formed through changing the mixed gel proportion, drying process and other processes. Subsequently, the fluorescent glue 4 is uniformly sprayed on a plurality of surfaces of the LED chip 6 coated with the silica gel, so that the package component emits light from multiple surfaces. The operating principle of the invention is as follows.

The metal reflective cup 11 is provided outside the insulating reflective cup 2, and the light absorption layer 3 is provided outside the metal reflective cup 11. A small amount of light emitted from the LED chip 6 is refracted by the insulating reflective cup 2 to the metal reflective cup 11 by which the light may be reflected, and a very small amount of light that continues to penetrate through the metal reflective cup 11 can also be completely absorbed by the light absorption layer 3 without causing the vignetting effect outside. The anti-reflection film 10 is provided on outer surface of the lens 9 internally mixed or externally coated with the phosphor to reduce the reflection. Surfaces of the LED chip 6 are coated with the highly refractive transparent silica gel layer 12 that increases the light transmittance, thereby the light saturation, color rendering index, chromaticity coordinate and color contrast of the present invention can be maintained to overcome the current shortcomings.

The lens 9 internally mixed or externally coated with phosphor is provided on upper surface of the fluorescent glue 4, the phosphor is subjected to repeated grinding and purification, and the specific proportion of the phosphor in the fluorescent glue is under control. Surfaces of the LED chip 6 are uniformly coated with a highly refractive transparent silica gel layer 12, and the transparent silica gel and the fluorescent glue are uniformly coated on a plurality of surfaces of the LED through electric heating and plating, increasing the light-emitting area, enhancing the light output efficiency, and further improving the light quality.

The high temperature resistant conductive film 5 and the sapphire-substrate ceramic film 8 collectively replace some of the conventional heat-dissipating aluminum substrates in the prior art. Without limitation of the aluminum substrate, the size and weight of the packaged components are reduced, and a chip-level package can be realized. At the same time, the thermally conductive adhesive layer 13 may be filled between the two bonding pads 7 of the LED flip chip and the sapphire-substrate ceramic film 8, greatly improving the heat dissipation performance.

The above embodiments are preferred embodiments of the present invention, but the embodiments of the present invention are not limited thereto. Any other changes, modifications, substitutions, combinations and simplifications made without departing from the spirit and principle of the present invention should be equivalent replacements, and are included within the scope of protection of the invention.

What is claimed is:

1. An LED flip-chip structure, comprising:
an LED chip;
a plurality of conductive films;
a ceramic film for heat dissipation arranged below the plurality of conductive films;
a sapphire substrate arranged below the ceramic film, the sapphire substrate is raised upward at a middle portion to form a protrusion;
a plurality of bonding pads, each of the plurality of bonding pads is connected at a bottom thereof to one of the plurality of conductive films and is connected at a top thereof to the LED chip;
an insulating reflective cup arranged on and fixed connected to the plurality of conductive films;
a silica gel layer,
a fluorescent glue;
a lens;
an anti-reflection film; and
a packaging adhesive layer,
wherein both of the LED chip and the plurality of bonding pads are located at a bottom of the insulating reflective cup; the silica gel layer, the fluorescent glue, the lens, the anti-reflection film and the packaging adhesive layer are all arranged within the insulating reflective cup and sequentially cover the LED chip from inside out, and both of the silica gel layer, the fluorescent glue cover at least five surfaces of the LED chip.

2. The LED flip-chip structure according to claim 1, wherein the protrusion is formed by the sapphire substrate, and an upper surface of the sapphire substrate at the protrusion abuts against a bottom of the LED chip.

3. The LED flip-chip structure according to claim 1, wherein the protrusion is formed by the sapphire substrate and the ceramic film, and an upper surface of the ceramic film at the protrusion abuts against a bottom of the LED chip.

4. The LED flip-chip structure according to claim 1, wherein the protrusion is formed by the sapphire substrate and a thermally conductive adhesive layer, and an upper surface of the thermally conductive adhesive layer at the protrusion abuts against a bottom of the LED chip.

5. The LED flip-chip structure according to claim 1, wherein the protrusion is formed by the sapphire substrate, the ceramic film and a thermally conductive adhesive layer sequentially, and an upper surface of the thermally conductive adhesive layer at the protrusion abuts against a bottom of the LED chip.

6. The LED flip-chip structure according to claim 1, wherein the lens is internally mixed or externally coated with phosphor for enhancing light transmission.

7. The LED flip-chip structure according to claim 1, wherein a metal reflective cup is provided outside the insulating reflective cup for enhancing light reflection and reducing light transmission.

8. The LED flip-chip structure according to claim 7, wherein a light absorption layer is provided outside the metal reflective cup to prevent light from scattering to outside.

9. The LED flip-chip structure according to claim 1, wherein an angle between an inner circumferential surface and a bottom surface of the insulating reflective cup is between 45° and 90°.

10. The LED flip-chip structure according to claim 9, wherein the insulating reflective cup is made of a transparent insulating material with a nonuniform density distribution, and density and thickness of the insulating reflective cup are both inversely proportional to a distance between the insulating reflective cup and the LED chip.
